(19) United States
(12) Patent Application Publication
(10) Pub. No.: US 2006/0128056 A1
(43) Pub. Date: Jun. 15, 2006

(54) Method of fabricating organic field effect transistor

(75) Inventors: Seong Hyun Kim, Daejeon (KR); Jung Hun Lee, Daejeon (KR); Tae Hyoung Zyung, Daejeon (KR)

Correspondence Address: MAYER, BROWN, ROWE & MAW LLP, 1909 K STREET, N.W., WASHINGTON, DC, 20006, US

(73) Assignee: ELECTRONICS AND TELECOMMUNICATIONS RESEARCH INSTITUTE

(21) Appl. No.: 11/153,339

(22) Filed: Jun. 16, 2005

(30) Foreign Application Priority Data
Dec. 9, 2004 (KR) 2004-103695

(51) Int. Cl. H01L 51/40

(52) U.S. Cl. 438/99

(57) ABSTRACT

Provided is a method of fabricating an organic field effect transistor (OFET). The method includes: forming an OFET pattern on a substrate, the OFET pattern having a gate electrode, a dielectric layer, a source electrode, a drain electrode, and an organic semiconductor layer; attaching a junction layer covered with a predetermined adhesive on the entire surface of the source and drain electrodes and the organic semiconductor layer and isolating the OFET pattern from the substrate; and transferring the isolated OFET pattern onto a plastic substrate that is prepared beforehand. In this method, the OFET pattern can be deposited without the temperature limit, the dielectric layer can be formed using a wide variety of materials, and the OFET pattern can be transferred in a very simple manner. Also, the junction layer functions as a passivation layer for protecting the organic semiconductor layer from external air and moisture so that the organic semiconductor layer can keep good performance for a long time.

### CROSS-REFERENCE TO RELATED APPLICATION

This application claims priority to and the benefit of Korean Patent Application No. 2004-103695, filed Dec. 9, 2004, the disclosure of which is incorporated herein by reference in its entirety.

### BACKGROUND

1. Field of the Invention

The present invention relates to a method of fabricating an organic field effect transistor (OFET) and, more specifically, to a method of fabricating an OFET on a plastic substrate using a transfer effect.

2. Discussion of Related Art

In general, an organic field effect transistor (OFET) has attracted much attention as the next-generation device because it can be fabricated on an elastic plastic substrate using a simple process at a low process temperature in comparison with a conventional silicon transistor.

However, when the OFET is fabricated on the plastic substrate, not only an organic semiconductor layer but also a dielectric layer should be capable of being formed at a low temperature. For this reason, it is impossible to use even a dielectric layer that has exhibited a good characteristic up to now, and the dielectric layer should be formed of only a limited kind of material.

In other words, because the plastic substrate is limited in temperature, materials for the dielectric layer are limited within narrow ranges and thus, it is difficult to secure desired materials that can be deposited at a low temperature. Moreover, a process of transferring an OFET pattern onto the plastic substrate using another substrate necessitates several complicated processes.

### SUMMARY OF THE INVENTION

The present invention is directed to a method of fabricating an organic field effect transistor (OFET), in which an OFET pattern is formed on a silicon substrate, which is free from temperature limit, such that the OFET pattern is not adhesive to the silicon substrate, and then the OFET pattern is isolated from the silicon substrate using a tape type junction layer and transferred onto a plastic substrate. As a result, since the OFET pattern is deposited without the temperature limit, a dielectric layer can be formed using a wide variety of materials, and the OFET pattern can be transferred in a very simple manner.

One aspect of the present invention is to provide a method of fabricating an OFET including: forming an OFET pattern on a substrate, the OFET pattern having a gate electrode, a dielectric layer, a source electrode, a drain electrode, and an organic semiconductor layer; attaching a junction layer covered with a predetermined adhesive on the entire surface of the source and drain electrodes and the organic semiconductor layer and isolating the OFET pattern from the substrate; and transferring the isolated OFET pattern onto a plastic substrate that is prepared beforehand.

The substrate may be formed of one of glass, silicon, plastic, and metal foil.

The plastic substrate may be formed of one of polyester (PET), polyethylenenaphthalate (PEN), polyethersulfone (PES), and polyimide (PI).

The junction layer may be formed of a 3M tape.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross sectional view illustrating a method of fabricating an organic field effect transistor (OFET) according to an exemplary embodiment of the present invention;

FIG. 2 is a cross sectional view of the OFET shown in FIG. 1, in which an OFET pattern is isolated from a silicon substrate using a 3M tape; and

FIG. 3 is a cross sectional view of the isolated OFET pattern shown in FIG. 2, in which the OFET pattern is attached to a plastic substrate.

### DETAILED DESCRIPTION OF EXEMPLARY EMBODIMENTS

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art.

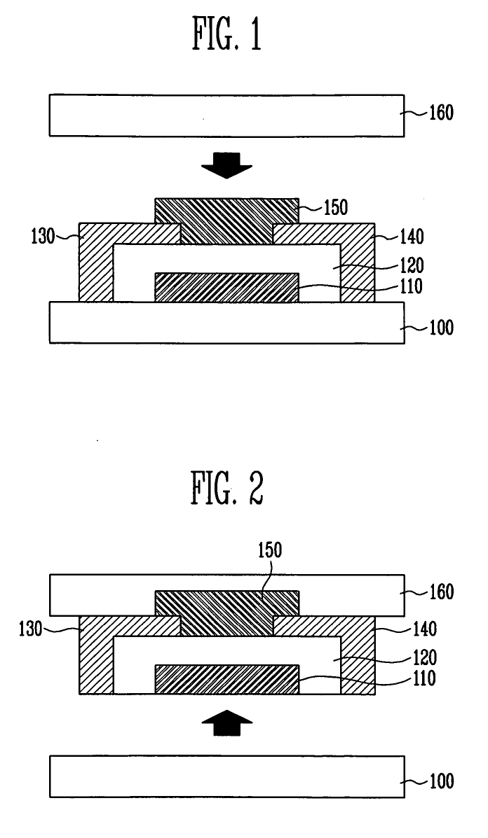

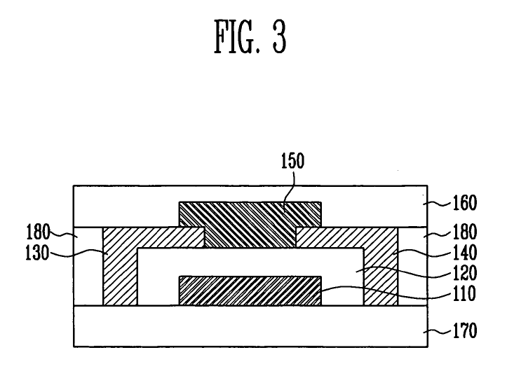

FIG. 1 is a cross sectional view illustrating a method of fabricating an organic field effect transistor (OFET) according to an exemplary embodiment of the present invention, FIG. 2 is a cross sectional view of the OFET shown in FIG. 1, in which an OFET pattern is isolated from a silicon substrate using a 3M tape, and FIG. 3 is a cross sectional view of the isolated OFET pattern shown in FIG. 2, in which the OFET pattern is attached to a plastic substrate.

Referring to FIGS. 1 through 3, the OFET according to the exemplary embodiment of the present invention includes a gate electrode 110, a dielectric layer 120, a source electrode 130, a drain electrode 140, and an organic semiconductor layer 150. The gate electrode 110 is disposed on a predetermined region of a substrate 100. The dielectric layer 120 is disposed on the substrate 100 and the gate electrode 110 to cover the gate electrode 110. The source and drain electrodes 130 and 140 are disposed on both sides of the substrate 100 and the dielectric layer 120 such that a portion of the dielectric layer 120 is exposed. The organic semiconductor layer 150 is disposed on the exposed portion of the dielectric layer 120 and portions of the source and drain electrodes 130 and 140.

In order to fabricate the OFET having the above-described structure, the gate electrode 110 is deposited on the substrate 100 using a predetermined patterned mask. The dielectric layer 120 is deposited on the gate electrode 110. The source and drain electrodes 130 and 140 are formed on the resultant structure, and the organic semiconductor layer 150 is deposited thereon.

The substrate 100 may be formed of one of glass, silicon, plastic, and metal foil.

The gate electrode 110 and the source and drain electrodes 130 and 140 may be formed of gold (Au) or any other metal that is not adhesive to the silicon substrate 100.

Also, the dielectric layer 120 may be formed of an organic material, but the present invention is not limited thereto. That is, it is possible to perform surface treatment on an organic/inorganic layer disposed on the silicon substrate 100 to degrade adhesion between the dielectric layer 120 and the silicon substrate 100. Alternatively, the dielectric layer 120 may be formed of any inorganic material that is not adhesive to the silicon substrate 100.

Further, the organic semiconductor layer 150 may be formed of pentacene, but the present invention is not limited thereto. In addition to pentacene, the organic semiconductor layer 150 may be formed of other organic materials having semiconductor characteristics.

Also, a junction layer covered with a predetermined adhesive, namely, a transfer tape 160, is disposed on the resultant structure to isolate an OFET pattern from the substrate 100. The transfer tape 160 may be formed of a 3M tape.

As shown in FIG. 2, the transfer tape 160 is attached to the entire top surface of the source and drain electrodes 130 and 140 and the organic semiconductor layer 150, and then the OFET pattern is isolated from the substrate 100.

As shown in FIG. 3, the isolated OFET pattern is transferred onto a plastic substrate 170, which is prepared beforehand.

In this case, a passivation layer 180 is formed using an additional junction material to reinforce adhesion between the OFET pattern and the plastic substrate 170 and cut off external air and moisture. Thus, while the OFET pattern is being transferred onto the plastic substrate 170, the organic semiconductor layer 150 is cut off from the external air and moisture. Thus, the transfer tape 160 functions as a passivation layer to improve the endurance of the organic semiconductor layer 150.

Meanwhile, the plastic substrate 170 may be formed of one selected from the group consisting of polyester (PET), polyethylenenaphthalate (PEN), polyethersulfone (PES), and polyimide (PI).

As described above, according to the method of fabricating an OFET, an OFET pattern is formed on a silicon substrate, which is free from temperature limit, such that the OFET pattern is not adhesive to the silicon substrate. Thereafter, the OFET pattern is isolated from the silicon substrate using a junction layer formed of a 3M tape and then transferred onto a plastic substrate. As a result, because the OFET pattern can be deposited without the temperature limit, a dielectric layer can be formed using a wide variety of materials, and the OFET pattern can be transferred in a very simple manner. Further, the junction layer also functions as a passivation layer so that the organic semiconductor layer is protected from external air and moisture. Thus, the organic semiconductor layer can keep good performance for a long time.

Although exemplary embodiments of the present invention have been described with reference to the attached drawings, the present invention is not limited to these embodiments, and it should be appreciated to those skilled in the art that a variety of modifications and changes can be made without departing from the spirit and scope of the present invention.

What is claimed is:

1. A method of fabricating an organic field effect transistor (OFET), comprising:
forming an OFET pattern on a substrate, the OFET pattern having a gate electrode, a dielectric layer, a source electrode, a drain electrode, and an organic semiconductor layer;
attaching a junction layer covered with a predetermined adhesive on the entire surface of the source and drain electrodes and the organic semiconductor layer and isolating the OFET pattern from the substrate; and
transferring the isolated OFET pattern onto a plastic substrate that is prepared beforehand.

2. The method according to claim 1, wherein the substrate is formed of one selected from the group consisting of glass, silicon, plastic, and metal foil.

3. The method according to claim 1, wherein the plastic substrate is formed of one selected from the group consisting of polyester (PET), polyethylenenaphthalate (PEN), polyethersulfone (PES), and polyimide (PI).

4. The method according to claim 1, wherein the junction layer is formed of a 3M tape.

5. The method according to claim 1, wherein the junction layer is formed of one selected from the group consisting of plastic, rubber, paper, and metal foil.

6. The method according to claim 1, wherein transferring the isolated OFET onto the plastic substrate is performed using a predetermined junction material.

7. The method according to claim 1, wherein transferring the isolated OFET onto the plastic substrate includes depositing a passivation layer on both sides of the junction layer and the plastic substrate to protect the OFET pattern from external air and moisture.
